(19) United States
(12) Patent Application Publication
(10) Pub. No.: US 2015/0252990 A1
(43) Pub. Date: Sep. 10, 2015

(54) LIGHT EMITTING MODULE AND LAMP BULB STRUCTURE

(71) Applicant: LUSTROUS TECHNOLOGY LTD., NEW TAIPEI CITY (TW)

(72) Inventors: DAWSON LIU, TAIPEI CITY (TW); JUEI-KHAI LIU, KEELUNG CITY (TW); CHIN-KAI HUANG, YILAN COUNTY (TW)

(73) Assignee: LUSTROUS TECHNOLOGY LTD., NEW TAIPEI CITY (TW)

(21) Appl. No.: 14/202,603

(22) Filed: Mar. 10, 2014

(51) Int. Cl. F21V 23/00; F21V 13/04; H05K 1/18

(52) U.S. Cl. CPC F21V 23/005; H05K 1/189; F21V 13/04; F21Y 2101/02

(57) ABSTRACT

A light emitting module includes a base unit, a substrate unit, a light emitting unit and a driving unit. The base unit includes a base body having a horizontal carrying surface and at least one inclined carrying surface. The inclined carrying surface is inclined by a predetermined angle relative to the horizontal carrying surface. The substrate unit includes a bendable substrate disposed on the base body. The bendable substrate has a horizontal portion disposed on the horizontal carrying surface, at least one inclined portion disposed on the inclined carrying surface, and at least one bending portion disposed between the horizontal and the inclined portions. The inclined portion is inclined by a predetermined angle relative to the horizontal portion. The light emitting unit includes at least one light emitting group disposed on the horizontal portion. The driving unit includes a plurality of electronic components disposed on the inclined portion.

### BACKGROUND OF THE INVENTION

1. Field of the Invention

The instant disclosure relates to a light emitting module and a lamp bulb structure, and more particularly to a light emitting module and a lamp bulb structure for placing a plurality of LED chips and a driving circuit on the same bendable substrate.

2. Description of Related Art

The invention of the lamp greatly changed the style of building construction and the lifestyle of human beings, allowing people to work during the night. Traditional lighting devices such as lamps that adopt incandescent bulbs, fluorescent bulbs, or power-saving bulbs have been generally well-developed and used intensively for indoor illumination. Moreover, compared to the newly developed light emitting diode (LED) lamps, these traditional lamps have the disadvantages of quick attenuation, high power consumption, high heat generation, short service life, high fragility, and being not recyclable. Thus, various high-powered LED lamps are created to replace the traditional lighting devices.

### SUMMARY OF THE INVENTION

One aspect of the instant disclosure relates to a light emitting module and a lamp bulb structure for placing a plurality of LED chips and a driving circuit on the same bendable substrate.

One of the embodiments of the instant disclosure provides a light emitting module, comprising: a base unit, a substrate unit, a light emitting unit and a driving unit. The base unit includes a base body, wherein the base body has a horizontal carrying surface and at least one inclined carrying surface connected to the horizontal carrying surface, and the at least one inclined carrying surface is inclined by a predetermined angle with respect to the horizontal carrying surface. The substrate unit includes a bendable substrate disposed on the base body, wherein the bendable substrate has a horizontal portion disposed on the horizontal carrying surface, at least one inclined portion disposed on the at least one inclined carrying surface and connected to the horizontal portion, and at least one bending portion disposed between the horizontal portion and the at least one inclined portion, and the at least one inclined portion is inclined by a predetermined angle with respect to the horizontal portion. The light emitting unit includes at least one light emitting group disposed on the horizontal portion of the bendable substrate, wherein the at least one light emitting group is electrically connected to the bendable substrate. The driving unit includes a plurality of electronic components disposed on the at least one inclined portion of the bendable substrate, wherein the electronic components are electrically connected to the at least one light emitting group through the bendable substrate.

More precisely, the at least one inclined carrying surface is inclinedly and downwardly extended from the horizontal carrying surface, and the at least one inclined portion is inclinedly and downwardly extended from the horizontal portion, wherein the at least one bending portion has at least one cutting groove disposed between the horizontal portion and the at least one inclined portion, and the at least one cutting groove is disposed on the top surface of the bendable substrate.

More precisely, the at least one inclined carrying surface is inclinedly and downwardly extended from the horizontal carrying surface, and the at least one inclined portion is inclinedly and downwardly extended from the horizontal portion, wherein the at least one bending portion has a plurality of through holes disposed between the horizontal portion and the at least one inclined portion, and the through holes pass through the bendable substrate.

Another one of the embodiments of the instant disclosure provides a light emitting module, comprising: a base unit, a substrate unit, a light emitting unit and a driving unit. The base unit includes a base body, wherein the base body has a horizontal carrying surface and at least two inclined carrying surfaces respectively connected to two opposite lateral sides of the horizontal carrying surface, and the at least two inclined carrying surfaces are inclined by a predetermined angle with respect to the horizontal carrying surface. The substrate unit includes a bendable substrate disposed on the base body, wherein the bendable substrate has a horizontal portion disposed on the horizontal carrying surface, at least two inclined portions respectively disposed on the at least two inclined carrying surfaces and respectively connected to two opposite lateral sides of the horizontal portion, and at least two bending portions, each of the at least two bending portions is disposed between the horizontal portion and the corresponding inclined portion, and the at least two inclined portions are inclined by a predetermined angle with respect to the horizontal portion. The light emitting unit includes at least one light emitting group disposed on the horizontal portion of the bendable substrate, wherein the at least one light emitting group is electrically connected to the bendable substrate. The driving unit includes a plurality of electronic components disposed on the at least two inclined portions of the bendable substrate, wherein the electronic components are electrically connected to the at least one light emitting group through the bendable substrate.

More precisely, the at least two inclined carrying surfaces are respectively extended inclinedly and downwardly from the two opposite lateral sides of the horizontal carrying surface, and the at least two inclined portions are respectively extended inclinedly and downwardly from the two opposite lateral sides of the horizontal portion, wherein each of the at least two bending portions has at least one cutting groove disposed between the horizontal portion and the corresponding inclined portion, and the at least one cutting groove of each bending portion is disposed on the top surface of the bendable substrate.

More precisely, the at least two inclined carrying surfaces are respectively extended inclinedly and downwardly from the two opposite lateral sides of the horizontal carrying surface, and the at least two inclined portions are respectively extended inclinedly and downwardly from the two opposite lateral sides of the horizontal portion, wherein each of the at least two bending portions has a plurality of through holes disposed between the horizontal portion and the corresponding inclined portion, and the through holes of each bending portion pass through the bendable substrate.

Yet another one of the embodiments of the instant disclosure provides a lamp bulb structure, comprising: a lamp bulb module and a light emitting module disposed inside the lamp bulb module. The light emitting module includes: a base unit, a substrate unit, a light emitting unit and a driving unit. The base unit includes a base body, wherein the base body has a horizontal carrying surface and at least one inclined carrying surface connected to the horizontal carrying surface, and the at least one inclined carrying surface is inclined by a predetermined angle with respect to the horizontal carrying surface. The substrate unit includes a bendable substrate disposed on the base body, wherein the bendable substrate has a horizontal portion disposed on the horizontal carrying surface, at least one inclined portion disposed on the at least one inclined carrying surface and connected to the horizontal portion, and at least one bending portion disposed between the horizontal portion and the at least one inclined portion, and the at least one inclined portion is inclined by a predetermined angle with respect to the horizontal portion. The light emitting unit includes at least one light emitting group disposed on the horizontal portion of the bendable substrate, wherein the at least one light emitting group is electrically connected to the bendable substrate. The driving unit includes a plurality of electronic components disposed on the at least one inclined portion of the bendable substrate, wherein the electronic components are electrically connected to the at least one light emitting group through the bendable substrate.

Therefore, because the light emitting unit includes at least one light emitting group disposed on the horizontal portion of the bendable substrate and the driving unit includes a plurality of electronic components disposed on the at least one inclined portion of the bendable substrate, the at least one light emitting group and the driving circuit (i.e., the electronic components) can be disposed on the same bendable substrate. In addition, after bending the bendable substrate, the at least two inclined portions can be inclined by the second predetermined angle with respect to the horizontal portion and the electronic components can follow the at least two inclined portions to be moved downwardly and inclinedly, thus the design of bending the at least two inclined portions can prevent the whole light source generated by the at least one light emitting group from being shaded by the electronic component that is adjacent to the at least one light emitting group. Hence, the illumination range of the light source generated by the at least one light emitting group can be increased.

To further understand the techniques, means and effects of the instant disclosure applied for achieving the prescribed objectives, the following detailed descriptions and appended drawings are hereby referred, such that, through which, the purposes, features and aspects of the instant disclosure can be thoroughly and concretely appreciated. However, the appended drawings are provided solely for reference and illustration, without any intention to limit the instant disclosure.

### BRIEF DESCRIPTION OF THE DRAWINGS

FIG. 1 shows a lateral, cross-sectional, schematic view of before bending the bendable substrate of the light emitting module according to the first embodiment of the instant disclosure;

FIG. 2 shows a lateral, cross-sectional, schematic view of after bending the bendable substrate of the light emitting module according to the first embodiment of the instant disclosure;

FIG. 3 shows a lateral, cross-sectional, schematic view of the light emitting module according to the first embodiment of the instant disclosure;

FIG. 4 shows a lateral, cross-sectional, schematic view of the light emitting module using an optical reflector according to the first embodiment of the instant disclosure;

FIG. 5 shows a lateral, cross-sectional, schematic view of the light emitting module using an optical lens according to the first embodiment of the instant disclosure;

FIG. 6 shows a lateral, cross-sectional, schematic view of before bending the bendable substrate of the light emitting module according to the second embodiment of the instant disclosure;

FIG. 7 shows a lateral, cross-sectional, schematic view of after bending the bendable substrate of the light emitting module according to the second embodiment of the instant disclosure;

FIG. 8 shows a lateral, cross-sectional, schematic view of the light emitting module according to the second embodiment of the instant disclosure; and

FIG. 9 shows a lateral, cross-sectional, schematic view of the light emitting module installed in the lamp bulb module to form a lamp bulb structure according to the third embodiment of the instant disclosure.

### DETAILED DESCRIPTION OF THE PREFERRED EMBODIMENTS

### First Embodiment

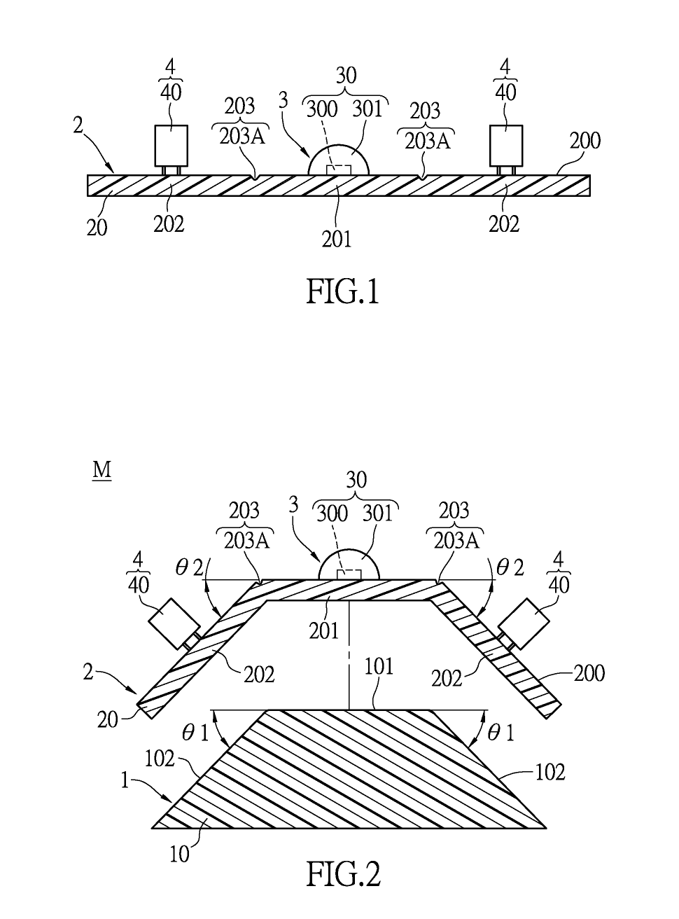

Referring to FIG. 1 to FIG. 3, where the first embodiment of the instant disclosure provides a light emitting module M, comprising: a base unit 1, a substrate unit 2, a light emitting unit 3 and a driving unit 4.

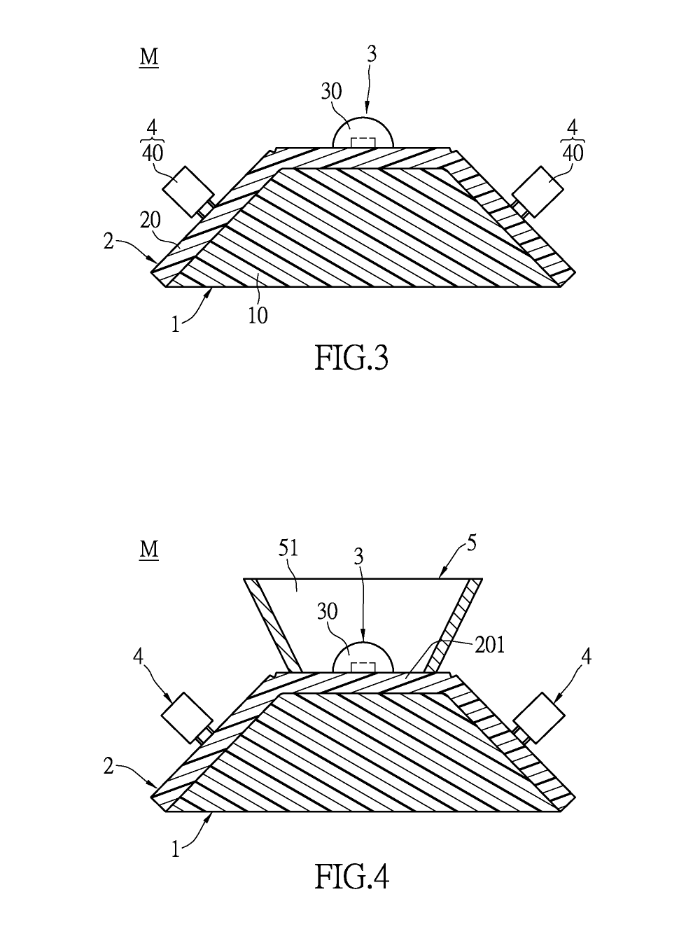

First, referring to FIG. 2 and FIG. 3, the base unit 1 includes a base body 10. More precisely, the base body 10 has a horizontal carrying surface 101 (or a reference carrying surface) and at least two inclined (slant) carrying surfaces 102 respectively connected to two opposite lateral sides of the horizontal carrying surface 101, and the at least two inclined carrying surfaces 102 are inclined by a first predetermined angle θ1 with respect to (respect to) the horizontal carrying surface 101. For example, the base body 10 may be a heat dissipating base, and the at least two inclined carrying surfaces 102 are respectively extended inclinedly and downwardly from the two opposite lateral sides of the horizontal carrying surface 101.

Moreover, referring to FIG. 2 and FIG. 3, the substrate unit 2 includes a bendable substrate 20 disposed on the base body 10. More precisely, the bendable substrate 20 has a horizontal portion 201 disposed on the horizontal carrying surface 101, at least two inclined portions 202 respectively disposed on the at least two inclined carrying surfaces 102 and respectively connected to two opposite lateral sides of the horizontal portion 201, and at least two bending portions 203. Each of the at least two bending portions 203 is disposed between the horizontal portion 201 and the corresponding inclined portion 202, and the at least two inclined portions 202 are inclined by a second predetermined angle θ2 with respect to the horizontal portion 201. For example, the bendable substrate 20 may be a bendable circuit substrate. In addition, each of the at least two bending portions 203 has at least one cutting groove 203A (such as a V-cut groove) disposed between the horizontal portion 201 and the corresponding inclined portion 202, and the cutting groove 203A of each bending portion 203 can be disposed on the top surface 200 or the bottom surface (not labeled) of the bendable substrate 20.

More precisely, referring to FIG. 1 and FIG. 2, FIG. 1 shows a cross-sectional, schematic view of before bending the bendable substrate 20, and FIG. 2 shows a cross-sectional, schematic view of after bending the bendable substrate 20. The at least two inclined portions 202 can be inclined by the second predetermined angle θ2 with respect to the horizontal portion 201 due to the design of the cutting groove 203A of the at least two bending portions 203 disposed between the horizontal portion 201 and the corresponding inclined portion 202, thus the at least two inclined portions 202 are respectively extended inclinedly and downwardly from the two opposite lateral sides of the horizontal portion 201.

Furthermore, referring to FIG. 2 and FIG. 3, the light emitting unit 3 includes at least one light emitting group 30 disposed on the horizontal portion 201 of the bendable substrate 20, and the light emitting group 30 is electrically connected to the bendable substrate 20. For example, the light emitting group 30 includes at least one LED chip 300 disposed on the horizontal portion 201 and an encapsulation gel body 301 disposed on the horizontal portion 201 for enclosing the LED chip 300. In addition, the LED chip 300 can be disposed on the horizontal portion 201 and electrically connected to the horizontal portion 201 by a COB (Chip On Board) method, and then encapsulation gel body 301 can be used to enclose the LED chip 300 in order to protect the LED chip 300. Moreover, when the LED chip 300 is a blue LED chip and the encapsulation gel body 301 is a phosphor resin body, the blue light source generated by the blue LED chip can be transformed into a white light source through the phosphor resin body. However, the light emitting unit 3 used in the first embodiment is merely an example and is not meant to limit the instant disclosure.

Besides, referring to FIG. 1 to FIG. 3, the driving unit 4 includes a plurality of electronic components 40 disposed on the at least two inclined portions 202 of the bendable substrate 20, and the electronic components 40 are electrically connected to the light emitting group 30 through the bendable substrate 20. For example, the electronic components 40 can be mated with each other to form a driving circuit, so that the light emitting group 30 and the driving circuit (i.e., the electronic components 40) can be disposed on the same bendable substrate 20. In addition, the electronic component 40 may be a capacitor, an inductor or any electronic element of big size etc. As shown in FIG. 1, before bending the bendable substrate 20, one part of the light source generated by the light emitting group 30 is shaded by the electronic component 40 that is adjacent to the light emitting group 30. However, as shown in FIG. 2, after bending the bendable substrate 20, the at least two inclined portions 202 can be inclined by the second predetermined angle θ2 with respect to the horizontal portion 201 and the electronic components 40 can follow the at least two inclined portions 202 to be moved downwardly and inclinedly, thus the design of bending the at least two inclined portions 202 can prevent the whole light source generated by the light emitting group 30 from being shaded by the electronic component 40 that is adjacent to the light emitting group 30. Hence, the illumination range of the light source generated by the light emitting group 30 can be increased.

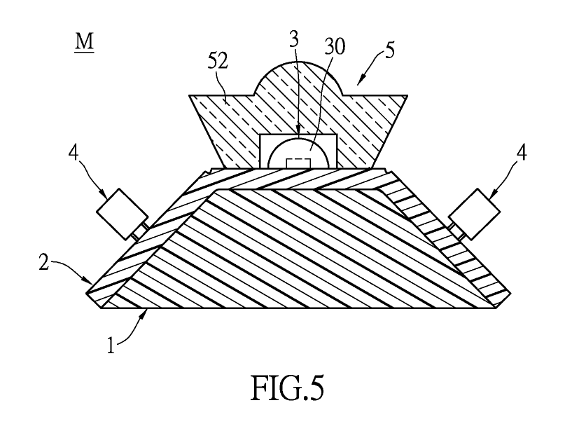

More precisely, referring to FIG. 4 and FIG. 5, the light emitting module M further comprises an optical unit 5. First, referring to FIG. 3 and FIG. 4, the optical unit 5 includes an optical reflector 51 disposed on the horizontal portion 201 of the bendable substrate 20, and the light emitting group 30 of the light emitting unit 3 is disposed inside the optical reflector 51 and surrounded by the optical reflector 51, thus the light-concentrating effect of the light source generated by the light emitting group 30 can be increased through the optical reflector 51. In addition, referring to FIG. 3 and FIG. 5, the optical unit 5 includes an optical lens 52 disposed on the horizontal portion 201 of the bendable substrate 20, and the light emitting group 30 of the light emitting unit 3 is disposed between the horizontal portion 201 of the bendable substrate 20 and the optical lens 52 and covered up by the optical lens 52, thus the light-concentrating effect or the light-diffusing effect of the light source generated by the light emitting group 30 can be increased through the optical lens 52.

Of course, the first embodiment can only use at least one inclined carrying surface 102, at least one inclined portion 202 and at least one bending portion 203, thus the first embodiment of the instant disclosure provides another light emitting module M, comprising: a base unit 1, a substrate unit 2, a light emitting unit 3 and a driving unit 4. The base unit 1 includes a base body 10, the base body 10 has a horizontal carrying surface 101 and at least one inclined carrying surface 102 connected to the horizontal carrying surface 101, and the inclined carrying surface 102 is inclined by a first predetermined angle θ1 with respect to the horizontal carrying surface 101. The substrate unit 2 includes a bendable substrate 20 disposed on the base body 10, the bendable substrate 20 has a horizontal portion 201 disposed on the horizontal carrying surface 101, at least one inclined portion 202 disposed on the inclined carrying surface 102 and connected to the horizontal portion 201, and at least one bending portion 203 disposed between the horizontal portion 201 and the inclined portion 202, and the inclined portion 202 is inclined by a second predetermined angle θ2 with respect to the horizontal portion 201. The light emitting unit 3 includes at least one light emitting group 30 disposed on the horizontal portion 201 of the bendable substrate 30, and the light emitting group 30 is electrically connected to the bendable substrate 20. The driving unit 4 includes a plurality of electronic components 40 disposed on the inclined portion 202 of the bendable substrate 20, and the electronic components 40 are electrically connected to the light emitting group 30 through the bendable substrate 20.

More precisely, the inclined carrying surface 102 is inclinedly and downwardly extended from the horizontal carrying surface 101, and the inclined portion 202 is inclinedly and downwardly extended from the horizontal portion 201. In addition, the bending portion 203 has at least one cutting groove 203A disposed between the horizontal portion 201 and the inclined portion 202, and the cutting groove 203A is disposed on the top surface 200 or the bottom surface of the bendable substrate 20.

### Second Embodiment

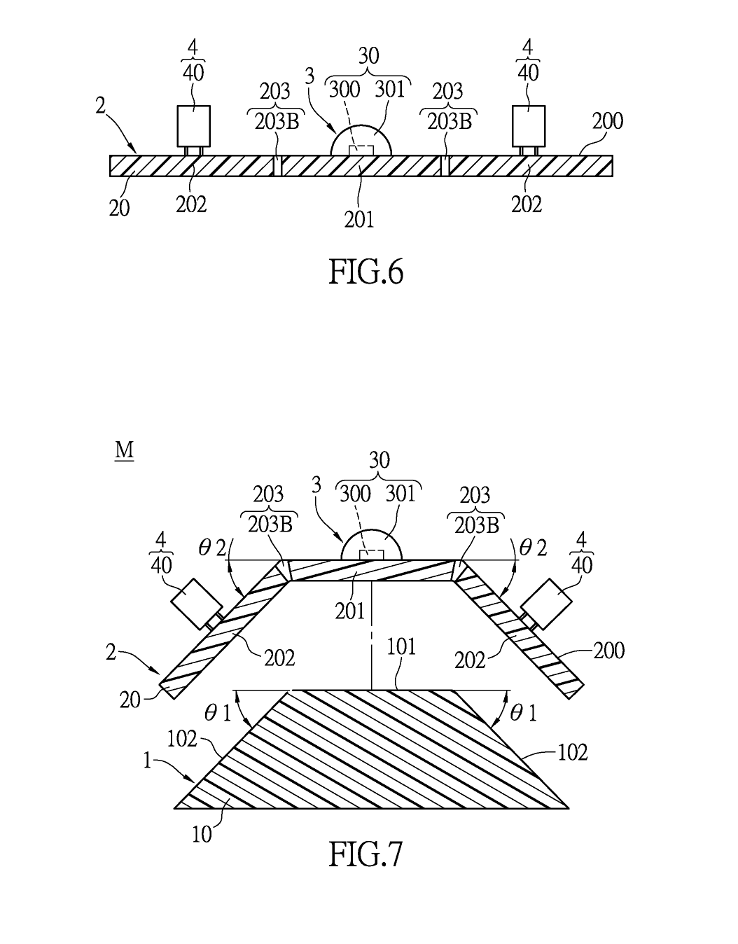

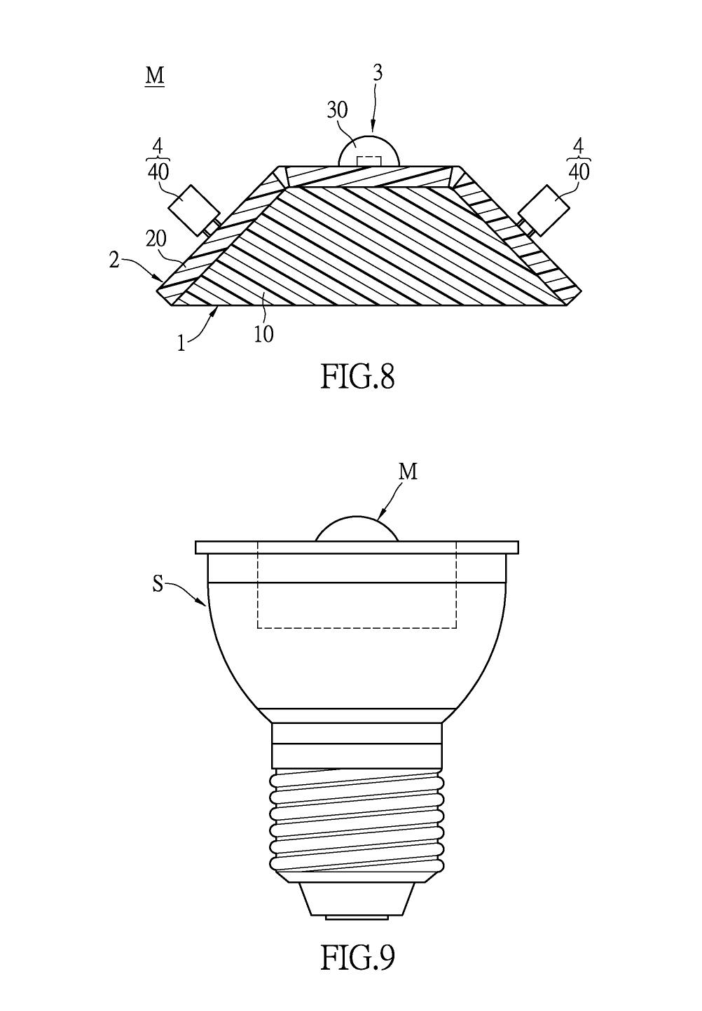

Referring to FIG. 6 to FIG. 8, where the second embodiment of the instant disclosure provides a light emitting module M, comprising: a base unit 1, a substrate unit 2, a light emitting unit 3 and a driving unit 4. Comparing FIGS. 6-8 with FIGS. 1-3, the difference between the second embodiment and the first embodiment is as follows: in the second embodiment, each of the at least two bending portions 203 has a plurality of through holes 203B disposed between the horizontal portion 201 and the corresponding inclined portion 202, and the through holes 203B of each bending portion 203 can pass through the bendable substrate 20. Of course, the second embodiment can only use at least one inclined carrying surface 102, at least one inclined portion 202 and at least one bending portion 203, thus the inclined carrying surface 102 can be inclinedly and downwardly extended from the horizontal carrying surface 101, the inclined portion 202 can be inclinedly and downwardly extended from the horizontal portion 201, and the bending portion 203 has a plurality of through holes 203B disposed between the horizontal portion 201 and the inclined portion 202.

### Third Embodiment

Referring to FIG. 9, where the third embodiment of the instant disclosure provides a lamp bulb structure comprising: a lamp bulb module S and a light emitting module M, and the light emitting module M is disposed inside the lamp bulb module S.

For example, referring to FIGS. 5 and 9, the light emitting module M includes a base unit 1, a substrate unit 2, a light emitting unit 3, a driving unit 4 and an optical unit 5. The base unit 1 includes a base body 10, the base body 10 has a horizontal carrying surface 101 and at least one inclined carrying surface 102 connected to the horizontal carrying surface 101, and the inclined carrying surface 102 is inclined by a first predetermined angle θ1 with respect to the horizontal carrying surface 101. The substrate unit 2 includes a bendable substrate 20 disposed on the base body 10, the bendable substrate 20 has a horizontal portion 201 disposed on the horizontal carrying surface 101, at least one inclined portion 202 disposed on the inclined carrying surface 102 and connected to the horizontal portion 201, and at least one bending portion 203 disposed between the horizontal portion 201 and the inclined portion 202, and the inclined portion 202 is inclined by a second predetermined angle θ2 with respect to the horizontal portion 201. The light emitting unit 3 includes at least one light emitting group 30 disposed on the horizontal portion 201 of the bendable substrate 30, and the light emitting group 30 is electrically connected to the bendable substrate 20. The driving unit 4 includes a plurality of electronic components 40 disposed on the inclined portion 202 of the bendable substrate 20, and the electronic components 40 are electrically connected to the light emitting group 30 through the bendable substrate 20. The optical unit 5 includes an optical lens 52 disposed on the horizontal portion 201 of the bendable substrate 20, and the light emitting group 30 of the light emitting unit 3 is disposed between the horizontal portion 201 of the bendable substrate 20 and the optical lens 52 and covered up by the optical lens 52.

In conclusion, because the light emitting unit 3 includes at least one light emitting group 30 disposed on the horizontal portion 201 of the bendable substrate 20 and the driving unit 4 includes a plurality of electronic components 40 disposed on the inclined portion 202 of the bendable substrate 20, the light emitting group 30 and the driving circuit (i.e., the electronic components 40) can be disposed on the same bendable substrate 20. In addition, after bending the bendable substrate 20, the at least two inclined portions 202 can be inclined by the second predetermined angle θ2 with respect to the horizontal portion 201 and the electronic components 40 can follow the at least two inclined portions 202 to be moved downwardly and inclinedly, thus the design of bending the at least two inclined portions 202 can prevent the whole light source generated by the light emitting group 30 from being shaded by the electronic component 40 that is adjacent to the light emitting group 30. Hence, the illumination range of the light source generated by the light emitting group 30 can be increased.

The above-mentioned descriptions merely represent the preferred embodiments of the instant disclosure, without any intention or ability to limit the scope of the instant disclosure which is fully described only within the following claims. Various equivalent changes, alterations or modifications based on the claims of instant disclosure are all, consequently, viewed as being embraced by the scope of the instant disclosure.

What is claimed is:

1. A light emitting module, comprising:
a base unit including a base body, wherein the base body has a horizontal carrying surface and at least one inclined carrying surface connected to the horizontal carrying surface, and the at least one inclined carrying surface is inclined by a predetermined angle with respect to the horizontal carrying surface;
a substrate unit including a bendable substrate disposed on the base body, wherein the bendable substrate has a horizontal portion disposed on the horizontal carrying surface, at least one inclined portion disposed on the at least one inclined carrying surface and connected to the horizontal portion, and at least one bending portion disposed between the horizontal portion and the at least one inclined portion, and the at least one inclined portion is inclined by a predetermined angle with respect to the horizontal portion;
a light emitting unit including at least one light emitting group disposed on the horizontal portion of the bendable substrate, wherein the at least one light emitting group is electrically connected to the bendable substrate; and
a driving unit including a plurality of electronic components disposed on the at least one inclined portion of the bendable substrate, wherein the electronic components are electrically connected to the at least one light emitting group through the bendable substrate.

2. The light emitting module of claim 1, wherein the at least one inclined carrying surface is inclinedly and downwardly extended from the horizontal carrying surface, and the at least one inclined portion is inclinedly and downwardly extended from the horizontal portion, wherein the at least one bending portion has at least one cutting groove disposed between the horizontal portion and the at least one inclined portion, and the at least one cutting groove is disposed on the top surface of the bendable substrate.

3. The light emitting module of claim 1, wherein the at least one inclined carrying surface is inclinedly and downwardly extended from the horizontal carrying surface, and the at least one inclined portion is inclinedly and downwardly extended from the horizontal portion, wherein the at least one bending portion has a plurality of through holes disposed between the horizontal portion and the at least one inclined portion, and the through holes pass through the bendable substrate.

4. The light emitting module of claim 1, further comprising: an optical unit including an optical reflector disposed on the horizontal portion of the bendable substrate, wherein the at least one light emitting group is disposed inside the optical reflector and surrounded by the optical reflector.

5. The light emitting module of claim 1, further comprising: an optical unit including an optical lens disposed on the horizontal portion of the bendable substrate, wherein the at least one light emitting group is disposed between the horizontal portion of the bendable substrate and the optical lens and covered up by the optical lens.

6. A light emitting module, comprising:
a base unit including a base body, wherein the base body has a horizontal carrying surface and at least two inclined carrying surfaces respectively connected to two opposite lateral sides of the horizontal carrying surface, and the at least two inclined carrying surfaces are inclined by a predetermined angle with respect to the horizontal carrying surface;
a substrate unit including a bendable substrate disposed on the base body, wherein the bendable substrate has a horizontal portion disposed on the horizontal carrying surface, at least two inclined portions respectively disposed on the at least two inclined carrying surfaces and respectively connected to two opposite lateral sides of the horizontal portion, and at least two bending portions, each of the at least two bending portions is disposed between the horizontal portion and the corresponding inclined portion, and the at least two inclined portions are inclined by a predetermined angle with respect to the horizontal portion;
a light emitting unit including at least one light emitting group disposed on the horizontal portion of the bendable substrate, wherein the at least one light emitting group is electrically connected to the bendable substrate; and
a driving unit including a plurality of electronic components disposed on the at least two inclined portions of the bendable substrate, wherein the electronic components are electrically connected to the at least one light emitting group through the bendable substrate.

7. The light emitting module of claim 6, wherein the at least two inclined carrying surfaces are respectively extended inclinedly and downwardly from the two opposite lateral sides of the horizontal carrying surface, and the at least two inclined portions are respectively extended inclinedly and downwardly from the two opposite lateral sides of the horizontal portion, wherein each of the at least two bending portions has at least one cutting groove disposed between the horizontal portion and the corresponding inclined portion, and the at least one cutting groove of each bending portion is disposed on the top surface of the bendable substrate.

8. The light emitting module of claim 6, wherein the at least two inclined carrying surfaces are respectively extended inclinedly and downwardly from the two opposite lateral sides of the horizontal carrying surface, and the at least two inclined portions are respectively extended inclinedly and downwardly from the two opposite lateral sides of the horizontal portion, wherein each of the at least two bending portions has a plurality of through holes disposed between the horizontal portion and the corresponding inclined portion, and the through holes of each bending portion pass through the bendable substrate.

9. A lamp bulb structure, comprising:
a lamp bulb module; and
a light emitting module disposed inside the lamp bulb module, wherein the light emitting module includes:
a base unit including a base body, wherein the base body has a horizontal carrying surface and at least one inclined carrying surface connected to the horizontal carrying surface, and the at least one inclined carrying surface is inclined by a predetermined angle with respect to the horizontal carrying surface;
a substrate unit including a bendable substrate disposed on the base body, wherein the bendable substrate has a horizontal portion disposed on the horizontal carrying surface, at least one inclined portion disposed on the at least one inclined carrying surface and connected to the horizontal portion, and at least one bending portion disposed between the horizontal portion and the at least one inclined portion, and the at least one inclined portion is inclined by a predetermined angle with respect to the horizontal portion;
a light emitting unit including at least one light emitting group disposed on the horizontal portion of the bendable substrate, wherein the at least one light emitting group is electrically connected to the bendable substrate; and
a driving unit including a plurality of electronic components disposed on the at least one inclined portion of the bendable substrate, wherein the electronic components are electrically connected to the at least one light emitting group through the bendable substrate.

10. The lamp bulb structure of claim 9, further comprising: an optical unit including an optical reflector or an optical lens disposed on the horizontal portion of the bendable substrate, wherein the at least one bending portion has at least one cutting groove or a plurality of through holes disposed between the horizontal portion and the at least one inclined portion.
